(19) United States
(12) Patent Application Publication
(10) Pub. No.: US 2026/0010679 A1
(43) Pub. Date: Jan. 8, 2026

(54) USER-DEFINED TECHNICAL DRAWING GENERATION USING GENERATIVE ARTIFICIAL INTELLIGENCE

(71) Applicant: Kyndryl, Inc., New York, NY (US)

(72) Inventors: Vinay Kumar Gajanana Hegde, Bangalore (IN); Omar Odibat, Cedar Park, TX (US); Ratchanon Eksombatchai, Bangkok (TH)

(21) Appl. No.: 18/765,394

(22) Filed: Jul. 8, 2024

(51) Int. Cl. G06F 30/27; G06F 16/901; G06F 30/17

(52) U.S. Cl. CPC G06F 30/27; G06F 16/9024; G06F 30/17

(57) ABSTRACT

Computer-implemented methods for a user-defined technical drawing generation system. Aspects include receiving user input about an overall object for a technical drawing. Aspects also include retrieving data from a knowledge database based on the user input. Aspects further include generating an augmented query based on the user input and the data from the knowledge database. Aspects also include generating an initial outline of the overall object for the technical drawing based on the augmented query using a generative artificial intelligence (AI) engine. Aspects further include refining the initial outline of the overall object by a refinement AI engine using a parameter for a component of the overall object. Aspects also include finalizing the overall object for the technical drawing.

### BACKGROUND

The present invention generally relates to technical drawings, and more specifically, to computer-implemented methods, computer systems, and computer program products configured and arranged for a user-defined technical drawing generation using generative artificial intelligence.

Technical drawings visually communicate how a system or architecture is constructed or functions. Technical drawings often utilize units of measurement, notations systems, perspectives, and other principles to ensure that the drawings are unambiguous and easily understood. Current tools used to generate technical drawings require a lot of effort to create a drawing and are prone to human error. For example, a user needs to define parameters for each component of the technical drawing, even dependent components and their ability to integrate into the technical drawing, their sizing, and their compatibility. Additionally, as users tend to focus on defining each parameter for each component for the technical drawing, optimization opportunities can be easily overlooked. In some cases, previously created components of technical drawings are reused to increase efficiency. However, reusing previously created components can contribute to the lack of adaption in newly created technical drawings as they reuse previously used designs and architecture

### SUMMARY

Embodiments of the present invention are directed to computer-implemented methods for a user-defined technical drawing generation system. A non-limiting computer-implemented method includes receiving user input about an overall object for a technical drawing. The method also includes retrieving data from a knowledge database based on the user input. The method further includes generating an augmented query based on the user input and the data from the knowledge database. The method also includes generating an initial outline of the overall object for the technical drawing based on the augmented query using a generative artificial intelligence (AI) engine. The method further includes refining the initial outline of the overall object by a refinement AI engine using a parameter for a component of the overall object. The method also includes finalizing the overall object for the technical drawing.

In one embodiment of the present invention, the method includes requesting a definition for the parameter for the component of the overall object. The method further includes receiving a value for the parameter for the component of the overall object.

In one embodiment of the present invention, the method includes requesting a definition for the parameter for the component of the overall object. The method also includes receiving a pass instruction for the component of the overall object. The method further includes using a default value for the parameter for the component of the overall object.

In one embodiment of the present invention, the method includes obtaining component data from a source. The method also includes storing parametric constraints and relational entities extracted from the component data in a graph database of the knowledge database. The method further includes indexing the parametric constraints and the relational entities in the graph database. The method also includes storing metadata extracted from the component data in a database in the knowledge database. The method further includes linking the database and the graph database of the knowledge database.

In one embodiment of the present invention, the method includes receiving an indication that a user disapproves the technical drawing. The method further includes requesting a new definition for the parameter for the component of the overall object. The method also includes regenerating the overall object by the refinement AI engine using the new definition for the parameter for the component of the overall object.

In one embodiment of the present invention, the method includes receiving an indication that a user approves the technical drawing. The method also includes processing the technical drawing for addition to the knowledge database.

In one embodiment of the present invention, the user input is a voice command, a text command, an audio file, a captured gesture, or a video file.

According to another non-limiting embodiment of the invention, a system is provided. The system includes a memory having computer readable instructions and one or more processors for executing the computer readable instructions, the computer readable instructions controlling the one or more processors to perform operations. The operations include receiving user input about an overall object for a technical drawing. The operations also include retrieving data from a knowledge database based on the user input. The operations further include generating an augmented query based on the user input and the data from the knowledge database. The operations also include generating an initial outline of the overall object for the technical drawing based on the augmented query using a generative artificial intelligence (AI) engine. The operations further include refining the initial outline of the overall object by a refinement AI engine using a parameter for a component of the overall object. The operations also include finalizing the overall object for the technical drawing.

According to another non-limiting embodiment of the invention, a computer program product is provided. The computer program product includes a computer-readable storage medium having program instructions embodied therewith, the program instructions executable by a processor to cause the processor to perform operations. The operations include receiving user input about an overall object for a technical drawing. The operations also include retrieving data from a knowledge database based on the user input. The operations further include generating an augmented query based on the user input and the data from the knowledge database. The operations also include generating an initial outline of the overall object for the technical drawing based on the augmented query using a generative artificial intelligence (AI) engine. The operations further include refining the initial outline of the overall object by a refinement AI engine using a parameter for a component of the overall object. The operations also include finalizing the overall object for the technical drawing.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 depicts a block diagram of an example computer system for use in conjunction with one or more embodiments of the present invention;

FIG. 2 depicts a block diagram of an example system for a user-defined technical drawing generation system in accordance with one or more embodiments of the present invention;

FIG. 3 is a flowchart of a computer-implemented method for building and maintaining a knowledge database for a user-defined technical drawing generation system in accordance with one or mor embodiments of the present invention.

FIG. 4 is a flowchart of a computer-implemented method for a user-defined technical drawing generation system in accordance with one or more embodiments of the present invention;

FIG. 5 depicts a cloud computing environment in accordance with one or more embodiments of the present invention; and

FIG. 6 depicts abstraction model layers in accordance with one or more embodiments of the present invention.

### DETAILED DESCRIPTION

Disclosed herein are methods, systems, and computer program products for a user-defined technical drawing generation system. As discussed above, current software applications used to create technical drawings require a lot of effort by a user and are prone to errors and missed opportunities. A user must build the architecture, define and draw parametric constraints covering all the components and create logical connections between all the components. Tracking the names of each component and their dependents components can be cumbersome and prone to human error. Manually creating complex structures in the technical drawings can result in mislabeled components, missing components, or misplaced components. In the event that a technical drawing requires a major change, the user must manually change many different components and may make mistakes or miss components that require change. Additionally, tools used to create technical drawings often lack the ability to add newer designs or components to the technical drawing from different sources, such as external databases, social media, and/or a database of components from a user. Users are also limited in the input type available for the tool, such as a mouse or smart pen.

The systems and methods described herein are directed to a user-defined technical drawing generation system using generative artificial intelligence (AI). The system generates a technical drawing of an overall object based on specifications provided by the user and augmented with data from a knowledge database. The knowledge database is a database of components used in technical drawings that is built and maintained by the system. The components available in the knowledge database are obtained from different sources, such as technical drawing application databases, search engines, an original equipment manufacturer (OEM) portal, social media, customized database, and the like. Using known techniques of generative AI, objects or images from the sources are analyzed, indexed, and stored in the knowledge database for use in the generation of technical drawings.

The user-defined technical drawing generation system receives input from a user and generates the requested technical drawing that includes all the relevant components of an architecture such as the naming, position, capacity, relationship and functionality of components of an overall object. In some embodiments, the technical drawing generated using generative AI also includes layering of the different components. During the generation of the technical drawing, the user-defined technical drawing generation system gives the user the option to define parametric constraints, such as dimension, capacity, and/or functionality, for each of the component. During the generation of the technical drawing, the user-defined technical drawing generation system predicts the relationship between the components based on data from the knowledge database.

The system provides the user the ability to define parameters and parametric constraints for each component of an object in a technical drawing, rather than having to manually edit each component individually as they are added to the drawing. Users are able to use text, voice, gesture, and other methods to provide input that will be converted using AI, such as natural language processing, prior to retrieving data or images from a knowledge database of components used for the generation of technical drawings. The user-defined technical drawing generation system enables a user to quickly make changes by providing input to the system, which will be used by generative AI to update or refine an existing technical drawing. In some embodiments, the system provides a comparison view which includes the technical drawing generated by generative AI using the data provided by the user and an alternative technical drawing generated without parameter definitions provided by the user.

Various aspects of the present disclosure are described by narrative text, flowcharts, block diagrams of computer systems, and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment ("CPP embodiment" or “CPP”) is a term used in the present disclosure to describe any set of one, or more, storage media (also called "mediums") collectively included in a set of one, or more, storage devices that collectively include machine readable code corresponding to instructions and/or data for performing computer operations specified in a given CPP claim. A "storage device" is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits / lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

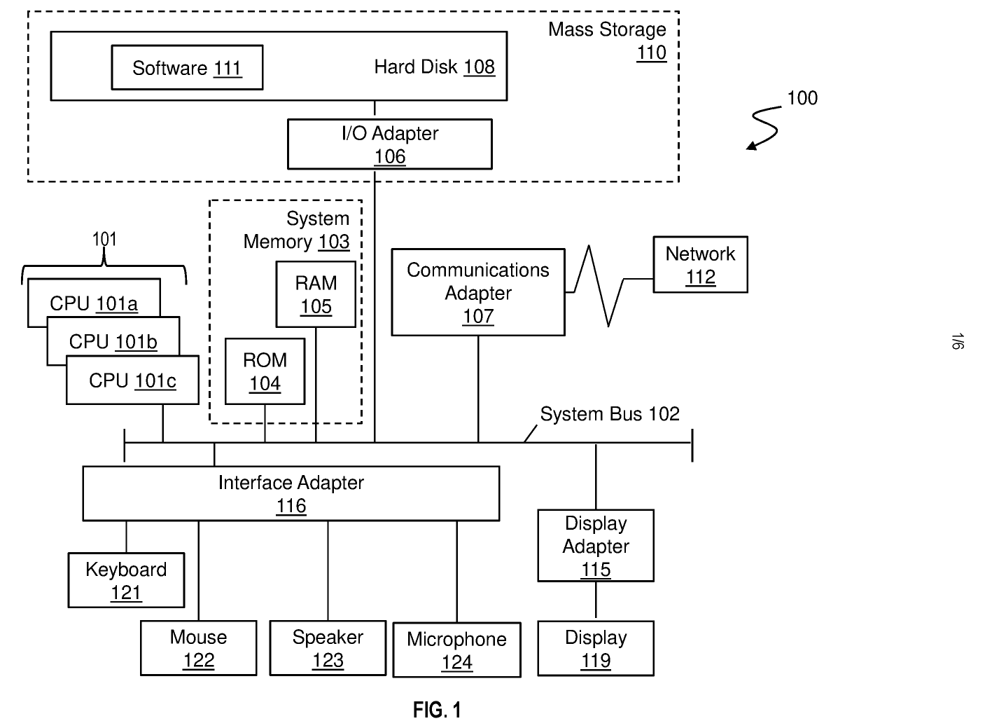

Turning now to FIG. 1, a computer system 100 is generally shown in accordance with one or more embodiments of the invention. The computer system 100 can be an electronic computer framework comprising and/or employing any number and combination of computing devices and networks utilizing various communication technologies, as described herein. The computer system 100 can be easily scalable, extensible, and modular, with the ability to change to different services or reconfigure some features independently of others. The computer system 100 may be, for example, a server, a desktop computer, a laptop computer, a tablet computer, or a smartphone. In some examples, the computer system 100 may be a cloud computing node. The computer system 100 may be described in the general context of computer system executable instructions, such as program modules, being executed by a computer system. Generally, program modules may include routines, programs, objects, components, logic, data structures, and so on that perform tasks or implement abstract data types. The computer system 100 may be practiced in distributed cloud computing environments where tasks are performed by remote processing devices that are linked through a communications network. In a distributed cloud computing environment, program modules may be located in both local and remote computer system storage media including memory storage devices.

As shown in FIG. 1, the computer system 100 has one or more central processing units (CPU(s)) 101a, 101b, 101c, etc., (collectively or generically referred to as processor(s) 101). The processors 101 can be a single-core processor, a multi-core processor, a computing cluster, or any number of other configurations. The processors 101, also referred to as processing circuits, are coupled via a system bus 102 to a system memory 103 and various other components. The system memory 103 can include a read only memory (ROM) 104 and a random-access memory (RAM) 105. The ROM 104 is coupled to the system bus 102 and may include a basic input/output system (BIOS) or its successors like Unified Extensible Firmware Interface (UEFI), which controls certain basic functions of the computer system 100. The RAM is read-write memory coupled to the system bus 102 for use by the processors 101. The system memory 103 provides temporary memory space for operations of said instructions during operation. The system memory 103 can include random access memory (RAM), read only memory, flash memory, or any other suitable memory systems.

The computer system 100 comprises an input/output (I/O) adapter 106 and a communications adapter 107 coupled to the system bus 102. The I/O adapter 106 may be a small computer system interface (SCSI) adapter that communicates with a hard disk 108 and/or any other similar component. The I/O adapter 106 and the hard disk 108 are collectively referred to herein as a mass storage 110.

The software 111 for execution on the computer system 100 may be stored in the mass storage 110. The mass storage 110 is an example of a tangible storage medium readable by the processors 101, where the software 111 is stored as instructions for execution by the processors 101 to cause the computer system 100 to operate, such as is described herein below with respect to the various Figures. Examples of computer program product and the execution of such instruction is discussed herein in more detail. The communications adapter 107 interconnects the system bus 102 with a network 112, which may be an outside network, enabling the computer system 100 to communicate with other such systems. In one embodiment, a portion of the system memory 103 and the mass storage 110 collectively store an operating system, which may be any appropriate operating system to coordinate the functions of the various components shown in FIG. 1.

Additional input/output devices are shown as connected to the system bus 102 via a display adapter 115 and an interface adapter 116. In one embodiment, the adapters 106, 107, 115, and 116 may be connected to one or more I/O buses that are connected to the system bus 102 via an intermediate bus bridge (not shown). A display 119 (e.g., a screen or a display monitor) is connected to the system bus 102 by the display adapter 115, which may include a graphics controller to improve the performance of graphics intensive applications and a video controller. A keyboard 121, a mouse 122, a speaker 123, a microphone 124, etc., can be interconnected to the system bus 102 via the interface adapter 116, which may include, for example, a Super I/O chip integrating multiple device adapters into a single integrated circuit. Suitable I/O buses for connecting peripheral devices such as hard disk controllers, network adapters, and graphics adapters typically include common protocols, such as the Peripheral Component Interconnect (PCI) and the Peripheral Component Interconnect Express (PCIe). Thus, as configured in FIG. 1, the computer system 100 includes processing capability in the form of the processors 101, storage capability including the system memory 103 and the mass storage 110, input means such as the keyboard 121, the mouse 122, and the microphone 124, and output capability including the speaker 123 and the display 119.

In some embodiments, the communications adapter 107 can transmit data using any suitable interface or protocol, such as the internet small computer system interface, among others. The network 112 may be a cellular network, a radio network, a wide area network (WAN), a local area network (LAN), or the Internet, among others. An external computing device may connect to the computer system 100 through the network 112. In some examples, an external computing device may be an external webserver or a cloud computing node.

It is to be understood that the block diagram of FIG. 1 is not intended to indicate that the computer system 100 is to include all the components shown in FIG. 1. Rather, the computer system 100 can include any appropriate fewer or additional components not illustrated in FIG. 1 (e.g., additional memory components, embedded controllers, modules, additional network interfaces, etc.). Further, the embodiments described herein with respect to computer system 100 may be implemented with any appropriate logic, wherein the logic, as referred to herein, can include any suitable hardware (e.g., a processor, an embedded controller, or an application specific integrated circuit, among others), software (e.g., an application, among others), firmware, or any suitable combination of hardware, software, and firmware, in various embodiments.

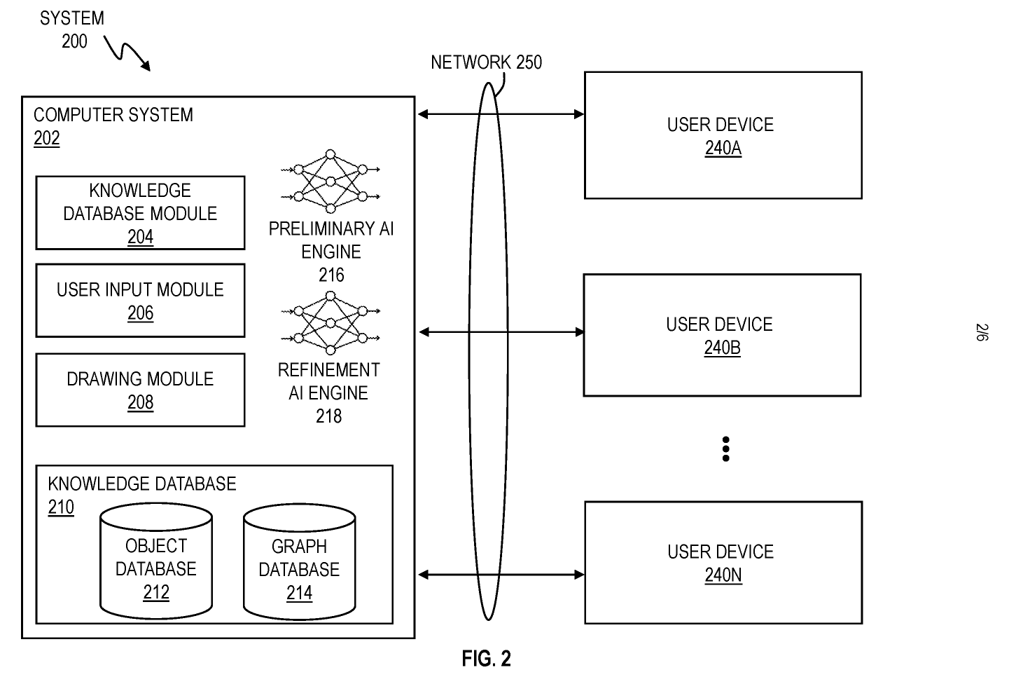

FIG. 2 depicts a block diagram of an example system 200 for a user-defined technical drawing generation system according to one or more embodiments. The system 200 includes a computer system 202 configured to communicate over a network 250 with many different user devices, such as a user device 240A, a user device 240B, through a user device 240N. The user devices 240A, 240B, through 240N can generally be referred to as user device 240 and are utilized to access the computing environment. The user device 240 can be a personal computer or laptop. The user device 240 can be a mobile device such as a cellular phone or tablet, or a smart device. A smart device is an electronic device, generally connected to other devices or networks via different wireless protocols that can operate to some extent interactively. Several notable types of smart devices are smartphones, smart speakers, tablets, smartwatches, smart bands, smart glasses, and many others.

The network 250 can be a wired and/or wireless communication network, and the communication network includes a telecommunications network, the public switched telephone network (PTSN), voice over IP (VOIP) network, etc. The communication network includes cellular networks, satellite networks, etc.

The user devices 240 can include various software and hardware components including software applications (apps) for communicating with one another over the network 250 as understood by one of ordinary skill in the art. The computer system 202, user device(s) 240, a knowledge database module 204, a user input module 206, a drawing module 208, a knowledge database 210 (that includes an object database 212 and a graph database 214), a preliminary AI engine 216, a refinement AI engine 218, etc., can include functionality and features of the computer system 100 in FIG. 1, including various hardware components and various software applications, such as the software 111, which can be executed as instructions on one or more processors 101 in order to perform actions according to one or more embodiments of the invention. The knowledge database module 204, user input module 206, drawing module 208, knowledge database 210, preliminary AI engine 216, and/or refinement AI engine 218 can include, be integrated with, and/or call other pieces of software, algorithms, application programming interfaces (APIs), etc., to operate as discussed herein.

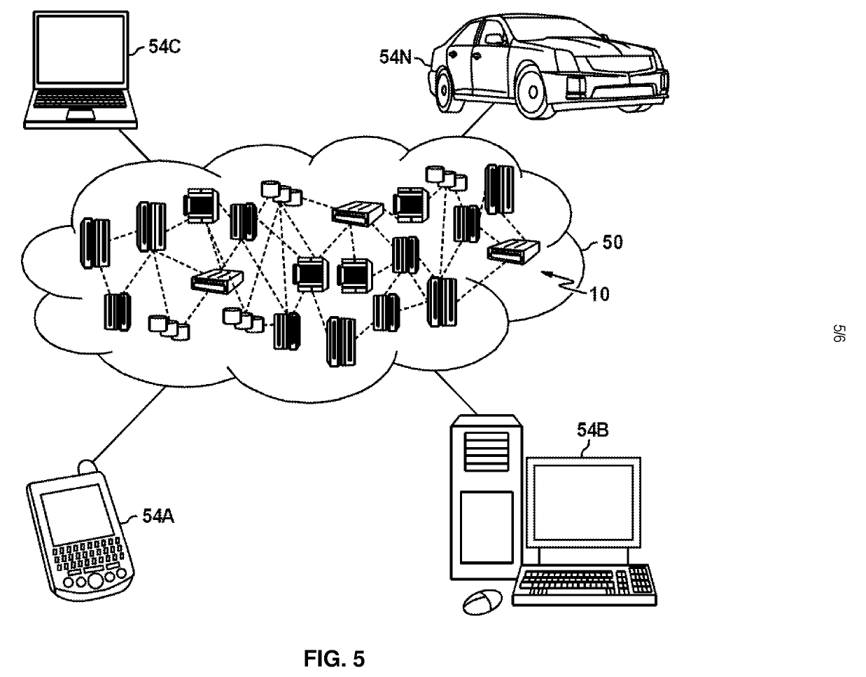

The computer system 202 may be representative of numerous computer systems and/or distributed computer systems configured to provide the knowledge database module 204, user input module 206, drawing module 208, knowledge database 210, preliminary AI engine 216, and/or refinement AI engine 218 to one or more user devices 240. The computer system 202 can be part of a cloud computing environment such as a cloud computing environment 50 depicted in FIG. 5, as discussed further herein.

In some embodiments, the computer system 202 can include one or more components for a user-defined technical drawing generation system. For example, the computer system 202 can include a knowledge database module 204. The knowledge database module 204 builds and maintains a database of components for technical drawings. In some embodiments, the knowledge database module 204 obtains data from different sources. Examples of sources include, but are not limited to, existing tool databases, such as AutoCAD^{TM} or DrawIO^{TM} databases, an original equipment manufacturer (OEM) portal, social media, an external customized database, and the like. In some embodiments, the knowledge database module 204 obtains or fetches data from the sources periodically. In some embodiments, the knowledge database module 204 receives an indication there is an update to a source and obtains or retrieves data from the source in response to the indication.

The knowledge database module 204 extracts parametric constraints and relational entities from an object from the source and indexes the parametric constraints and relational entities in a graph database 214 of the knowledge database 210. The knowledge database module 204 also analyzes the object obtained from the source and extracts metadata associated with the object and stores the object and the metadata in an object database 212 of the knowledge database 210. The knowledge database module 204 links the object database 212 and the graph database 214.

The user input module 206 of the user-defined technical drawing generation system facilitates requesting and receiving user input from a user device to use in the generation of the technical drawing. In some embodiments, the user input module 206 receives user input from a user device, such as user device 240. Examples of user input received from a user device 240 can include, but is not limited to, a voice command, a text command, an audio file, a captured gesture, and/or a video file. In some embodiments, the user provides user input about an overall object for a technical drawing. The overall object for a technical drawing is the main focus of the technical drawing. For example, if the user input indicates that the user wants a housing structure with three bedrooms and two bathrooms, the overall object is the housing structure and components of the housing structure are the three bedrooms and two bathrooms. In another example, if the user input indicates that the user needs a network application centric infrastructure (ACI) architecture, the network ACI architecture is the overall object.

In some embodiments, the user input module 206 receives user input and processes the information to generate a prompt. The user input module 206 communicates with the knowledge database module 204 to obtain data from the knowledge database 210 based on the prompt. The user input module 206 generates an augmented query based on the prompt and the data from the knowledge database module 204. Additionally, the user input module 206 generates requests for parameter definitions of components of the overall object and receives parametric and relational information of components of the overall object from the user device 240. The user input module 206 processes the received data, which will be used to refine the overall object of the technical drawing.

The drawing module 208 uses one or more generative AI engines, such as preliminary AI engine 216 and refinement AI engine 218 to generate an overall object for a technical drawing requested by a user of a user device 240. The drawing module 208 communicates with the user input module 206 to obtain the augmented query and relevant information. The drawing module 208 uses generative AI to generate an outline of the overall object based on the augmented query and relevant information. The drawing module 208 engages generative AI, such as the preliminary AI engine 216, to generate an initial overall object or outline of the overall object for the technical drawing.

In some embodiments, the drawing module 208 obtains parameter definitions for each of the components of the overall object from the user input module 206. In some embodiments, the drawing module 208 engages generative AI, such as refinement AI engine 218, to customize the overall object based on the received parameter definitions. If a parameter definition is not defined (e.g., user provided a pass instruction to move forward without the component or did not provide a definition), the drawing module 208 instructs the refinement AI engine 218 to use a default value for the parameter definition or to move forward without the component of the overall object. The drawing module 208 finalizes the technical drawing and facilitates presentation of the technical drawing on the user device 240. In some embodiments, the technical drawing is a file that contains the overall object, its components, and associated information. The technical drawing can be a known file format. The drawing module 208 facilitates transmission of the technical drawing to the user device 240 which can then open and display the technical drawing on a display of the user device 240.

In some embodiments, the user device transmits an indication that the finalized technical drawing is not approved, and the drawing module 208 requests additional parameter definitions and regenerates the overall object based on the data received. This process is repeated until approval of the technical drawing is received.

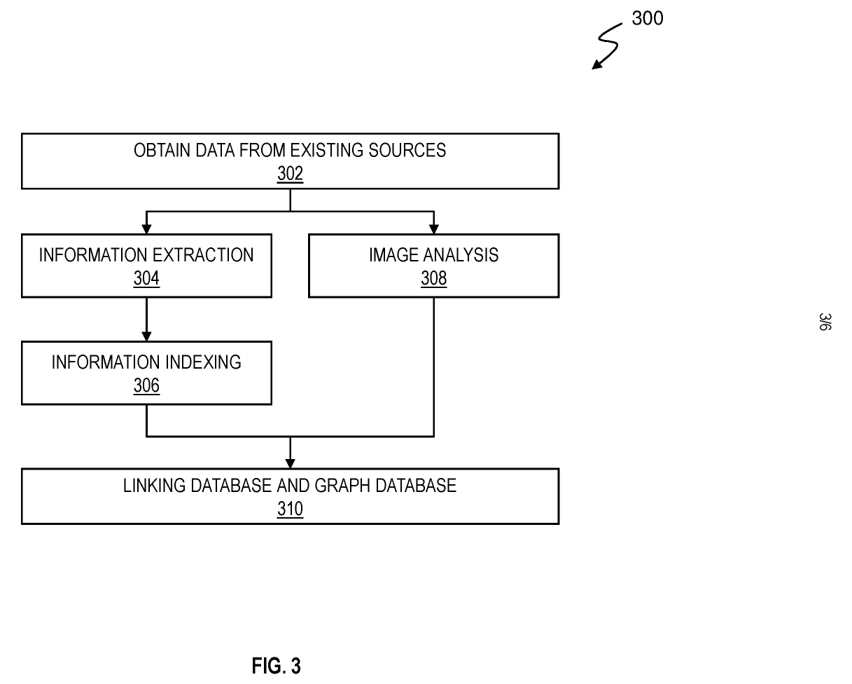

Now referring to FIG. 3, a flowchart of a computer-implemented method 300 for building and maintaining a knowledge database 210 for a user-defined technical drawing generation system in accordance with one or mor embodiments of the present invention. At block 302, the knowledge database module 204 obtains data from different sources. Examples of sources include existing tool databases, an original equipment manufacturer (OEM) portal, search engines, social media, an external customized database, and the like. Sources can be a collection of objects or images with associated text. In some embodiments, the knowledge database module 204 obtains or receives data from the sources periodically. In some embodiments, the knowledge database module 204 receives an indication there is an update to a source and obtains or retrieves data from the source in response to the indication.

Next at block 304, information is extracted from the sources. In some embodiments, the knowledge database module 204 extracts parametric constraints and relational entities from an object from the source using AI, such as large language models (LLMs). The LLMs can analyze data extracted from an object or image of a source and identify relational entities. Relational entities are components of a structure that connect or are otherwise associated with another component. In some embodiments, the LLMs determine parametric constraints of a component of an object. Parametric constraints are restrictions and limitations that are applied to two dimensional objects and ensure the object maintains it original structure by maintaining the relationships between an object and world space, between two objects, and/or within an object. Geometric constraints are used to determine the relationships between 2D geometric objects or points on objects relative to each other. Dimensional constraints are used to control the proportions and size of an object in a technical drawing. Dimensional constraints can constrain distances between objects, sizes of arcs and circles, and angles between objects.

Next at block 306, the knowledge database module 204 indexes the data extracted and obtained from objects of a source. For example, the parametric constraints and relational entities obtained at block 304 are indexed or organized and stored in a graph database 214 of the knowledge database 210. In some embodiments, the knowledge database module 204 uses one or more known indexing techniques to index the data extracted and obtained from objects of a source. In some embodiments, the objects are stored as nodes and the relationship between objects are stored as edges, providing a network of interconnected information that is quickly navigable.

In some embodiments, the actions of block 308 are executed concurrently or at substantially the same time as the actions of blocks 304 and 306. In some embodiments, the actions of block 308 are executed consecutively after blocks 304 and 306. At block 308, the knowledge database module 204 analyzes the object or image of the source. In some embodiments, the knowledge database module 204 uses AI, such as an LLM, to analyze the object obtained from the source and extract metadata associated with the object. Data obtained from the object or image can include identification of the different components of the object or image, attributes of the object or image, and/or interrelationships between components of the object or image. The knowledge database module 204 stores the object and the metadata in an object database 212 of the knowledge database 210.

Next, at block 310, the knowledge database module 204 links the object database 212 and the graph database 214. In some embodiments, the knowledge database module 204 links the object database 212 and the graph database 214 using known techniques for linking and associating related information in databases. Linking the object database 212 and the graph database 214 ensures that references within the graph database 214 can be traced back to the correct image or object in the object database 212. The link between the databases ensures that when information is retrieved using the structured data within the graph database 214, the system can also pull the associated raw images or objects from the object database 212, maintaining a connection between the extracted data and the image or object.

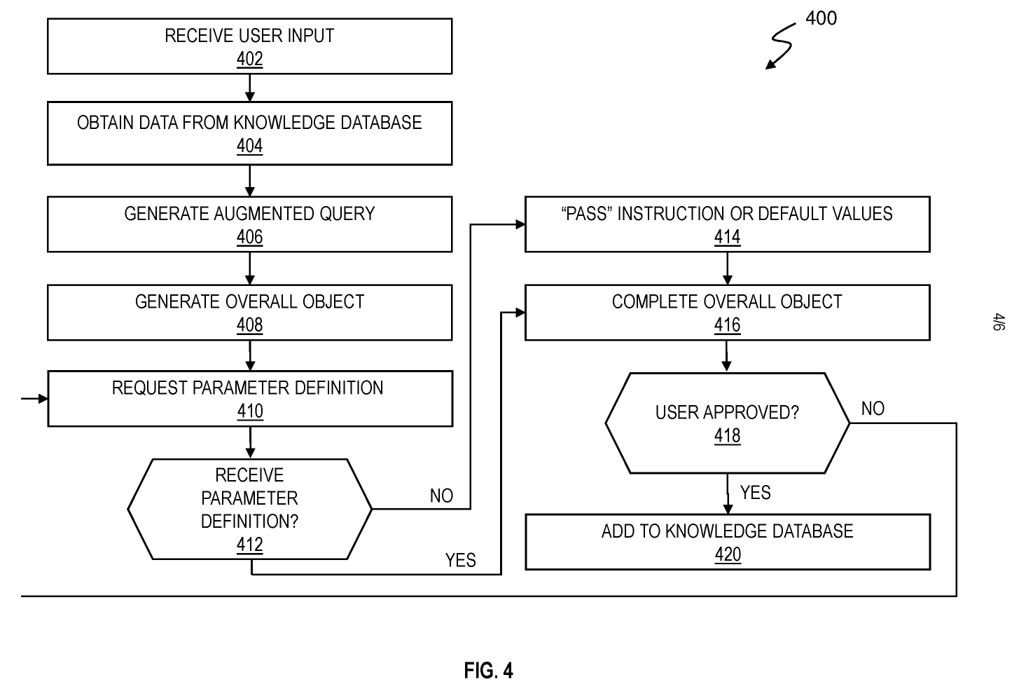

Now referring to FIG. 4, a flowchart of a computer-implemented method 400 for a user-defined technical drawing generation system is provided in accordance with one or more embodiments of the present invention. At block 402, the user input module 206 receives user input. In some embodiments, user input module 206 facilitates requesting and receiving user input from a user device 240 to use in the generation of a technical drawing. In some embodiments, the user input module 206 generates a prompt to display on a user device 240, requesting specifications of an overall object for the technical drawing. The user input module 206 receives user input from a user device 240. Examples of user input received from a user device 240 can include a voice command, a text command, an audio file, a captured gesture, and/or a video file. In some embodiments, the user provides user input about an overall object for a technical drawing. The overall object is the main focus of the technical drawing. The user input received is the starting point where the user defines the broad specifications of the desired overall object of the technical drawing.

Next at block 404, data is obtained from the knowledge database 210. In some embodiments, the user input module 206 receives user input and processes the information to generate a prompt. The user input module 206 communicates with the knowledge database module 204 to obtain data from the knowledge database 210 based on the prompt. The knowledge database module 204 retrieves structured data and relationships from the knowledge database 210 using the prompt generated from the user input. The structured data and relationships are used to supplement the initial input provided by the user with additional information and context.

Next at block 406, the user input module 206 generates an augmented query based on the prompt and the data retrieved by the knowledge database module 204 from the knowledge database 210. The data retrieved by the knowledge database module 204 includes parametric constraints and relational data for components of the overall object requested in the user input. The augmented query is a structured prompt that includes information from the user input and the data retrieved from the knowledge database 210 in a form that is compatible with generative AI, such as preliminary AI engine 216. In some embodiments, the augmented query and relevant information is transmitted to the drawing module 208.

At block 408, the overall object of the technical drawing is generated. In some embodiments, the drawing module 208 communicates with the user input module 206 to obtain the augmented query and relevant information. The drawing module 208 uses generative AI, such as preliminary AI engine 216, to generate an outline of the overall object based on the augmented query and relevant information. In some embodiments, the preliminary AI engine 216 receives and interprets the augmented query and relevant information, shaping the requirements specified by the user and supplemented by the data from the knowledge database 210 into a structured form. The preliminary AI engine 216 generates an outline of the overall object using its interpretation of the augmented query and relevant information.

At block 410, the drawing module 208 communicates with the user input module 206 to request parameter definitions of components of the overall object. In some embodiments, the user input module 206 generates prompts requesting the user to define each parameter or provide additional details associated with each component of the overall object.

At block 412, the user input module 206 receives data from the user device 240 responsive to the prompts requesting more specific details for components of the overall object. If at block 412, the user input module 206 determines that parameter definitions or other specific details are received, the method 400 proceeds to block 416. If at block 412, the user input module 206 determines that parameter definitions or other specific details are not received (e.g., no definitions are provided or a pass instruction is received), the method 400 proceeds to block 414.

At block 414, the user input module 206 determines that a parameter definition was not received and/or the user provided a pass instruction in lieu of a parameter definition. In some embodiments, a pass instruction is an indication to move forward with the technical drawing generation without the relevant component. For example, in response to determining that a parameter definition is not provided, the drawing module 208 instructs the refinement AI engine 218 to use a default value for the parameter definition. In response to determining that a pass instruction was provided for a component of the overall object, the drawing module 208 instructs the refinement AI engine 218 to continue with the generation of the overall object without the identified component.

At block 416, the overall object of the technical drawing is completed. In some embodiments, the drawing module 208 engages generative AI, such as refinement AI engine 218, to use the data received from the user device 240 in response to the request for parameter definitions to modify or otherwise refine one or more components of the overall object. In some embodiments, the refinement AI engine 218 modifies relationship between components, capacity of the component, and the like using its interpretation of the data received from the user device 240 for the parameter definitions.

The drawing module 208 finalizes the technical drawing and facilitates presentation of the technical drawing on the user device 240. In some embodiments, the user device transmits an indication that the finalized technical drawing is not approved, and the drawing module 208 requests additional parameter definitions and regenerates the overall object based on the data received. This process is repeated until approval of the technical drawing is received. The drawing module 208 facilitates the generation of the complete technical drawing of the overall object. In some embodiments, the technical drawing includes the logic, connectors, relationships, and sizing of the different components of the overall object requested by the user. In some embodiments, the technical drawing also includes a comparison to standard technical drawings of the overall object.

At block 418, the user input module 206 facilitates presentation of the finalized technical drawing on the user device 240 and requests user approval of the technical drawing. If at block 418, the user input module 206 receives an indication that the technical drawing is not approved, the method 400 proceeds back to block 410, where the system requests the user to redefine parameters for the components of the overall object and further refine the design of the overall object of the technical drawing based on the user feedback. If at block 418, the user input module 206 receives an indication that the technical drawing is approved, the method 400 proceeds to block 420. At block 420, the knowledge database module 204 receives the user-approved technical drawing and translates it into data that is compatible with the graph database 214 and the object database 212, ensuring that the final output is correctly represented within the knowledge database 210. In some embodiments, the output (i.e., finalized technical drawing) is saved and used for future technical drawing generations.

It is to be understood that although this disclosure includes a detailed description on cloud computing, implementation of the teachings recited herein are not limited to a cloud computing environment. Rather, embodiments of the present invention are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service’s provider.

Broad network access: capabilities are available over a network and accessed through standard mechanisms that promote use by heterogeneous thin or thick client platforms (e.g., mobile phones, laptops, and PDAs).

Resource pooling: the provider’s computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported, providing transparency for both the provider and consumer of the utilized service.

Service Models are as follows:

Software as a Service (SaaS): the capability provided to the consumer is to use the provider’s applications running on a cloud infrastructure. The applications are accessible from various client devices through a thin client interface such as a web browser (e.g., web-based e-mail). The consumer does not manage or control the underlying cloud infrastructure including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations.

Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It may be managed by the organization or a third party and may exist on-premises or off-premises.

Community cloud: the cloud infrastructure is shared by several organizations and supports a specific community that has shared concerns (e.g., mission, security requirements, policy, and compliance considerations). It may be managed by the organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service oriented with a focus on statelessness, low coupling, modularity, and semantic interoperability. At the heart of cloud computing is an infrastructure that includes a network of interconnected nodes.

Referring now to FIG. 5, illustrative cloud computing environment 50 is depicted. As shown, cloud computing environment 50 includes one or more cloud computing nodes 10 with which local computing devices used by cloud consumers, such as, for example, personal digital assistant (PDA) or cellular telephone 54A, desktop computer 54B, laptop computer 54C, and/or automobile computer system 54N may communicate. Nodes 10 may communicate with one another. They may be grouped (not shown) physically or virtually, in one or more networks, such as Private, Community, Public, or Hybrid clouds as described herein above, or a combination thereof. This allows cloud computing environment 50 to offer infrastructure, platforms and/or software as services for which a cloud consumer does not need to maintain resources on a local computing device. It is understood that the types of computing devices 54A-N shown in FIG. 5 are intended to be illustrative only and that computing nodes 10 and cloud computing environment 50 can communicate with any type of computerized device over any type of network and/or network addressable connection (e.g., using a web browser).

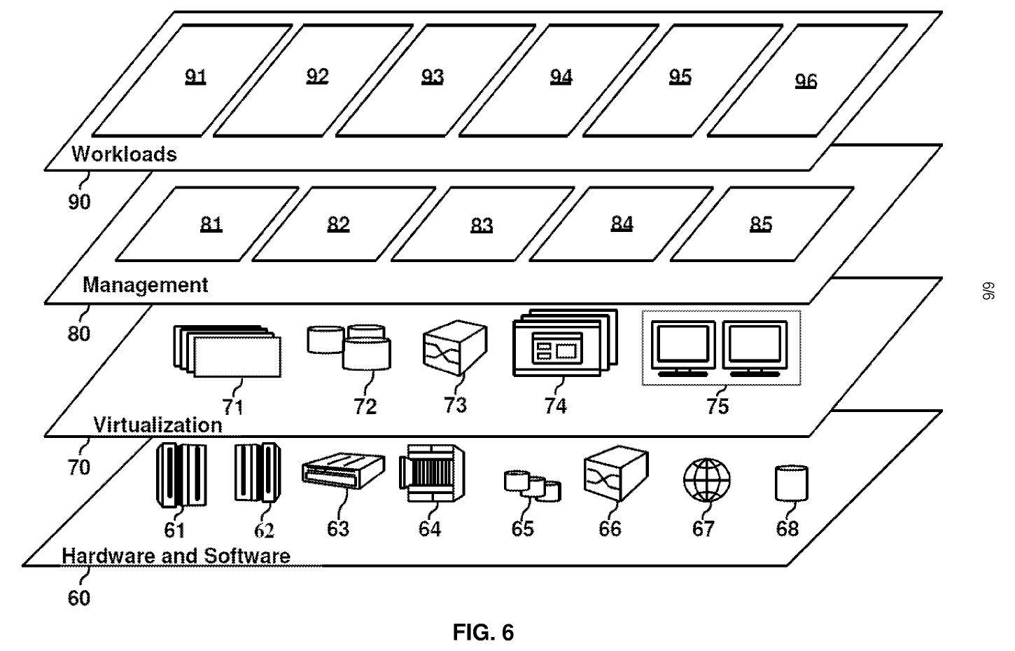

Referring now to FIG. 6, a set of functional abstraction layers provided by cloud computing environment 50 (depicted in FIG. 5) is shown. It should be understood in advance that the components, layers, and functions shown in FIG. 6 are intended to be illustrative only and embodiments of the invention are not limited thereto. As depicted, the following layers and corresponding functions are provided:

Hardware and software layer 60 includes hardware and software components. Examples of hardware components include: mainframes 61; RISC (Reduced Instruction Set Computer) architecture-based servers 62; servers 63; blade servers 64; storage devices 65; and networks and networking components 66. In some embodiments, software components include network application server software 67 and database software 68.

Virtualization layer 70 provides an abstraction layer from which the following examples of virtual entities may be provided: virtual servers 71; virtual storage 72; virtual networks 73, including virtual private networks; virtual applications and operating systems 74; and virtual clients 75.

In one example, management layer 80 may provide the functions described below. Resource provisioning 81 provides dynamic procurement of computing resources and other resources that are utilized to perform tasks within the cloud computing environment. Metering and Pricing 82 provides cost tracking as resources are utilized within the cloud computing environment, and billing or invoicing for consumption of these resources. In one example, these resources may include application software licenses. Security provides identity verification for cloud consumers and tasks, as well as protection for data and other resources. User portal 83 provides access to the cloud computing environment for consumers and system administrators. Service level management 84 provides cloud computing resource allocation and management such that required service levels are met. Service Level Agreement (SLA) planning and fulfillment 85 provides pre-arrangement for, and procurement of, cloud computing resources for which a future requirement is anticipated in accordance with an SLA.

Workloads layer 90 provides examples of functionality for which the cloud computing environment may be utilized. Examples of workloads and functions which may be provided from this layer include: mapping and navigation 91; software development and lifecycle management 92; virtual classroom education delivery 93; data analytics processing 94; transaction processing 95; and workloads and functions 96. Workloads and functions 96 can include generating technical drawings based on the input from a user and knowledge database. In some examples, the generative AI generates all relevant components of the technical drawing based on input provided by the user and leveraging the knowledge database built and maintained by generative AI using information collected from different sources. The workloads and functions are also used to refine and customize the technical drawing based on parameter definitions provided by the user for one or more components of the technical drawing.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for the purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted, or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ± 8% or 5%, or 2% of a given value.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the "C" programming language or similar programming languages. The computer readable program instructions may execute entirely on the user’s computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instruction by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A computer-implemented method comprising:
receiving user input about an overall object for a technical drawing;
retrieving data from a knowledge database based on the user input;
generating an augmented query based on the user input and the data from the knowledge database;
generating an initial outline of the overall object for the technical drawing based on the augmented query using a generative artificial intelligence (AI) engine;
refining the initial outline of the overall object by a refinement AI engine using a parameter for a component of the overall object; and
finalizing the overall object for the technical drawing.

2. The computer-implemented method of claim 1, further comprising:
requesting a definition for the parameter for the component of the overall object; and
receiving a value for the parameter for the component of the overall object.

3. The computer-implemented method of claim 1, further comprising:
requesting a definition for the parameter for the component of the overall object;
receiving a pass instruction for the component of the overall object; and
using a default value for the parameter for the component of the overall object.

4. The computer-implemented method of claim 1, further comprising:
obtaining component data from a source;
storing parametric constraints and relational entities extracted from the component data in a graph database of the knowledge database;
indexing the parametric constraints and the relational entities in the graph database;
storing metadata extracted from the component data in a database in the knowledge database; and
linking the database and the graph database of the knowledge database.

5. The computer-implemented method of claim 1, further comprising:
receiving an indication that a user disapproves the technical drawing;
. a new definition for the parameter for the component of the overall object;
. the overall object by the refinement AI engine using the new definition for the parameter for the component of the overall object.

6. The computer-implemented method of claim 1, further comprising:
receiving an indication that a user approves the technical drawing; and
processing the technical drawing for addition to the knowledge database.

7. The computer-implemented method of claim 1, wherein the user input is a voice command, a text command, an audio file, a captured gesture, or a video file.

8. A system comprising:
a memory having computer readable instructions; and
one or more processors for executing the computer readable instructions, the computer readable instructions controlling the one or more processors to perform operations comprising:
receiving user input about an overall object for a technical drawing;
retrieving data from a knowledge database based on the user input;
generating an augmented query based on the user input and the data from the knowledge database;
generating an initial outline of the overall object for the technical drawing based on the augmented query using a generative artificial intelligence (AI) engine;
refining the initial outline of the overall object by a refinement AI engine using a parameter for a component of the overall object; and
finalizing the overall object for the technical drawing.

9. The system of claim 8, wherein the operations further comprise:
requesting a definition for the parameter for the component of the overall object; and
receiving a value for the parameter for the component of the overall object.

10. The system of claim 8, wherein the operations further comprise:
requesting a definition for the parameter for the component of the overall object;
receiving a pass instruction for the component of the overall object; and
using a default value for the parameter for the component of the overall object.

11. The system of claim 8, wherein the operations further comprise:
obtaining component data from a source;
storing parametric constraints and relational entities extracted from the component data in a graph database of the knowledge database;
indexing the parametric constraints and the relational entities in the graph database;
storing metadata extracted from the component data in a database in the knowledge database; and
linking the database and the graph database of the knowledge database.

12. The system of claim 8, wherein the operations further comprise:
receiving an indication that a user disapproves the technical drawing;
. a new definition for the parameter for the component of the overall object;
. the overall object by the refinement AI engine using the new definition for the parameter for the component of the overall object.

13. The system of claim 8, wherein the operations further comprise:
receiving an indication that a user approves the technical drawing; and
processing the technical drawing for addition to the knowledge database.

14. The system of claim 8, wherein the user input is a voice command, a text command, an audio file, a captured gesture, or a video file.

15. A computer program product comprising a computer readable storage medium having program instructions embodied therewith, the program instructions executable by one or more processors to cause the one or more processors to perform operations comprising:
receiving user input about an overall object for a technical drawing;
retrieving data from a knowledge database based on the user input;
generating an augmented query based on the user input and the data from the knowledge database;
generating an initial outline of the overall object for the technical drawing based on the augmented query using a generative artificial intelligence (AI) engine;
refining the initial outline of the overall object by a refinement AI engine using a parameter for a component of the overall object; and
finalizing the overall object for the technical drawing.

16. The computer program product of claim 15, wherein the operations further comprise:
requesting a definition for the parameter for the component of the overall object; and
receiving a value for the parameter for the component of the overall object.

17. The computer program product of claim 15, wherein the operations further comprise:
requesting a definition for the parameter for the component of the overall object;
receiving a pass instruction for the component of the overall object; and
using a default value for the parameter for the component of the overall object.

18. The computer program product of claim 15, wherein the operations further comprise:
obtaining component data from a source;
storing parametric constraints and relational entities extracted from the component data in a graph database of the knowledge database;
indexing the parametric constraints and the relational entities in the graph database;
storing metadata extracted from the component data in a database in the knowledge database; and
linking the database and the graph database of the knowledge database.

19. The computer program product of claim 15, wherein the operations further comprise:
receiving an indication that a user disapproves the technical drawing;
. a new definition for the parameter for the component of the overall object;
. the overall object by the refinement AI engine using the new definition for the parameter for the component of the overall object.

20. The computer program product of claim 15, wherein the operations further comprise:
receiving an indication that a user approves the technical drawing; and
processing the technical drawing for addition to the knowledge database.
